(19) United States
(12) Patent Application Publication
(10) Pub. No.: US 2025/0359033 A1
(43) Pub. Date: Nov. 20, 2025

(54) Silicon On Insulator Device with Floating Body Effect Mitigation

(71) Applicant: Micron Technology, Inc., Boise, ID (US)

(72) Inventors: Kamal M. Karda, Boise, ID (US); Richard E. Fackenthal, Carmichael, CA (US); Duane R. Mills, Shingle Springs, CA (US); Eric S. Carman, San Francisco, CA (US); Daniele Vimercati, El Dorado Hills, CA (US)

(21) Appl. No.: 18/783,796

(22) Filed: Jul. 25, 2024

Related U.S. Application Data
(60) Provisional application No. 63/648,862, filed on May 17, 2024.

(51) Int. Cl. H10B 12/00; G11C 11/4093

(52) U.S. Cl. CPC H10B 12/50; G11C 11/4093; G11C 2211/4016

(57) ABSTRACT

Devices and methods include a partially depleted silicon on insulator device that comprises a transistor. The transistor comprises a gate terminal. The transistor also includes a first non-gate terminal and a second non-gate terminal. Moreover, the first non-gate terminal is coupled to a body of the partially depleted silicon on insulator device.

### CROSS-REFERENCE TO RELATED APPLICATIONS

This application claims priority to U.S. Provisional Application No. 63/648,862, filed May 17, 2024, which is incorporated by reference herein in its entirety.

### BACKGROUND

### Field of the Present Disclosure

Embodiments of the present disclosure relate generally to silicon on insulator devices. More specifically, embodiments of the present disclosure relate to extending a state that is at least based in part on a strobe.

### Description of Related Art

Generally, a computing system may include electronic devices (e.g., memory devices) that, in operation, communicate information via electrical signals. These electronic devices often utilize semiconductor devices. Steadily these devices are required to be faster and smaller. Indeed, Moore's law projects a rate at which the number of transistors in ICs increases. For some time, bulk metal oxide semiconductor field effect transistors (MOSFETs) have been used to meet these projections using device scaling. However, as smaller and smaller transistors are used, additional challenges arise. Specifically, smaller bulk MOSFETs (e.g., CMOS) devices may be subject to short channel effect (SCE) issues that cause a leakage current through the devices to increase. Shortening the channel length by scaling down the bulk MOSFETs may also decrease the threshold voltage of the transistors. Moreover, smaller bulk MOSFETs may also be prone to “latch up” by creating a low impedance path between a supply pin and ground. Additionally, smaller bulk MOSFETs may be prone to parasitic capacitance issues. To mitigate these various issues, silicon on insulator (SOI) devices may be used. SOI devices may use simple manufacturing processes but be less prone to these issues. SOI devices layer silicon (or another semiconductor) layer on top of an insulator layer (e.g., an oxide (e.g., silicon dioxide) or other insulator) that is sandwiched on top of a substrate (e.g., silicon). However, the thickness of the silicon layer may impact performance of the transistor. Specifically, in a fully depleted SOI (FDSOI) MOSFET, variation in the thickness of the SOI layer may cause its threshold voltage to fluctuate. Furthermore, FDSOI devices may be subject to disturb issues due to capacitive coupling. To reduce these issues, a partially depleted SOI (PDSOI) MOSFET may be used that has a thicker silicon layer. This thicker layer may mitigate disturb and/or threshold voltage problems. PDSOI have more silicon that causes a portion of the silicon to form a neutral region or body. However, PDSOI devices may be subject to a floating body effect (FBE) where a body potential of the transistor can form a capacitor against the insulation layer. This FBE issue may cause a “kink” that increases the channel current and may speed operation of the PDSOI devices but may also increase leakage currents when the PDSOI devices are off.

Embodiments of the present disclosure may be directed to one or more of the problems set forth above.

### BRIEF DESCRIPTION OF THE DRAWINGS

FIG. 1 is a simplified block diagram illustrating certain features of a memory device having a silicon on insulator (SOI) device, according to an embodiment of the present disclosure;

FIG. 2 is a diagram of an embodiment of the SOI device of FIG. 1 with a neutral body, according to an embodiment of the present disclosure;

FIG. 3 is a diagram of an example circuit of the memory device incorporating the SOI device of FIG. 2, according to an embodiment of the present disclosure;

FIG. 4 is a response curve of the SOI device of FIG. 2, according to an embodiment of the present disclosure;

FIG. 5 is a circuit diagram with the SOI device of FIG. 2 incorporating floating body effect (FBE) mitigation, according to an embodiment of the present disclosure; and

FIG. 6 is a flow diagram of a process for implementing the SOI device of FIG. 3, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As discussed below, a partially depleted silicon on insulator (PDSOI) transistor has a neutral region or body that forms in the silicon layer. In some embodiments, this body may have its own terminal and/or be tied to the gate terminal. If the body is not coupled to the gate terminal, the body floats. This floating body causes floating body effects (FBE) due to an accumulation of holes at the source end and electronics at the drain causing an accumulation of holes in the neutral body causing a potential of the body region to rise and decrease a threshold voltage of the transistor. This body potential and related threshold voltage change may cause a kink effect that is a sharp rise in drain current as the drain current increases. This change in threshold voltage may cause an inversely proportional increase in a leakage current through the transistor. To mitigate this leakage current, the body (e.g., via a body terminal) may be coupled to one of the non-gate terminals of the transistor. As used herein, non-gate terminals are terminals that can act the source or drain of the transistor. For instance, when the transistor is used to couple a local digit line to a global digit line based on a word line coupled to the gate terminal, the local digit line may be coupled to a first non-gate terminal to act as a source and/or drain terminal and also to the body terminal. As discussed below, this connection ensures that the body voltage of the transistor is the same as the local digit line at all times and is well defined. Therefore, a disturb event from other circuitry will not raise the body potential to arbitrarily increase a current (Ioff) through the transistor when off as leakage along with the body voltage being deterministic.

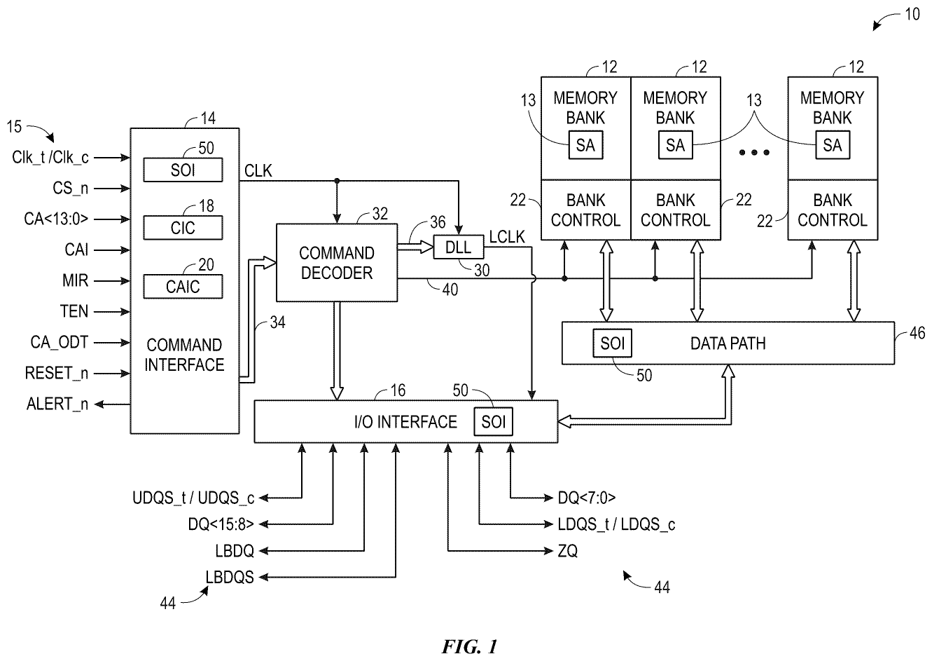

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random-access memory (DDR5 SDRAM) device. Various features of DDR5 SDRAM allow for reduced power consumption, more bandwidth and more storage capacity compared to prior generations of DDR SDRAM.

The memory device 10 may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabyte (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory banks 12 and/or bank control blocks 22 include sense amplifiers 13. As previously noted, sense amplifiers 13 are used by the memory device 10 during read operations. Specifically, read circuitry of the memory device 10 utilizes the sense amplifiers 13 to receive low voltage (e.g., low differential) signals from the memory cells of the memory banks 12 and amplifies the small voltage differences to enable the memory device 10 to interpret the data properly.

The memory device 10 may include a command interface 14 and an input/output (I/O) interface 16. The command interface 14 is configured to provide a number of signals (e.g., signals 15) from an external (e.g., host) device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, the true clock signal Clk_t and the bar clock signal Clk_c. The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 18 receives the true clock signal Clk_t and the bar clock signal Clk_c and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the I/O interface 16, for instance, and is used as a timing signal for determining an output timing of read data. In some embodiments, the clock input circuit 18 may include circuitry that splits the clock signal into multiple (e.g., 4) phases. The clock input circuit 18 may also include phase detection circuitry to detect which phase receives a first pulse when sets of pulses occur too frequently to enable the clock input circuit 18 to reset between sets of pulses.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes the bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20, which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the data path 46, which includes a plurality of bi-directional data buses. Data IO signals, generally referred to as DQ signals, are generally transmitted and received in one or more bi-directional data busses. For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback data signal (LBDQ) and loopback strobe signal (LBDQS) may be provided to the memory device 10 through the IO interface 16. The loopback data signal and the loopback strobe signal may be used during a test or debugging phase to set the memory device 10 into a mode wherein signals are looped back through the memory device 10 through the same pin. For instance, the loopback signal may be used to set the memory device 10 to test the data output (DQ) of the memory device 10. Loopback may include both LBDQ and LBDQS or possibly just a loopback data pin. This is generally intended to be used to monitor the data captured by the memory device 10 at the IO interface 16. LBDQ may be indicative of a target memory device, such as memory device 10, data operation and, thus, may be analyzed to monitor (e.g., debug and/or perform diagnostics on) data operation of the target memory device. Additionally, LBDQS may be indicative of a target memory device, such as memory device 10, strobe operation (e.g., clocking of data operation) and, thus, may be analyzed to monitor (e.g., debug and/or perform diagnostics on) strobe operation of the target memory device.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description. Furthermore, although the foregoing discusses the memory device 10 as being a DDR5 device, the memory device 10 may be any suitable device (e.g., a double data rate type 4 DRAM (DDR4), a ferroelectric RAM device, or a combination of different types of memory devices).

As may be appreciated, at least some portions of the memory device 10, such as the command interface 14, the I/O interface 16, the data path 46, and/or the memory banks 12 may utilize silicon on insulator (SOI) devices 50, such as transistors, that are formed with an insulator layer sandwiched between a silicon layer (or other semiconductor) and a substrate layer. Furthermore, although the SOI devices 50 are discussed in relation to memory devices 10, similar SOI devices 50 may be utilized in any suitable electronic devices where relatively small SOI-based transistors may be used.

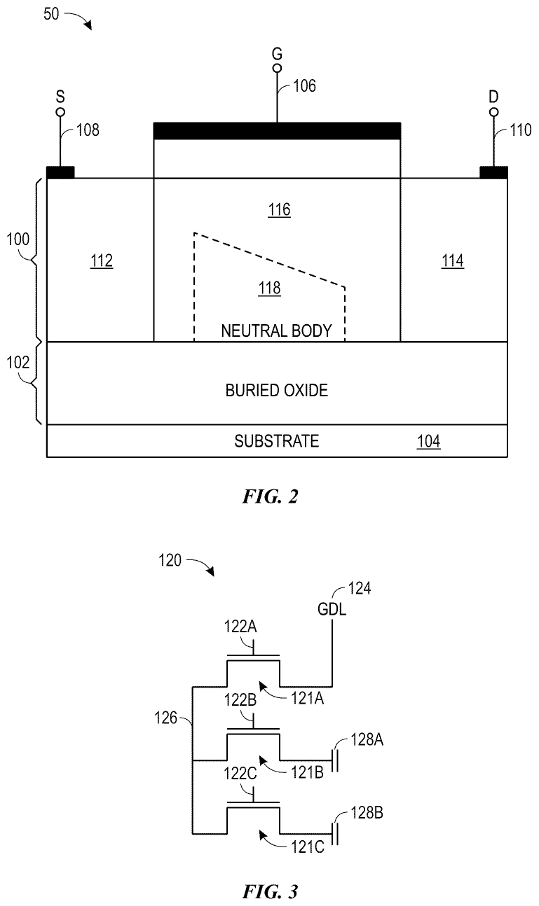

FIG. 2 is a diagram of an embodiment of the SOI device 50. As illustrated, the SOI device 50 includes a silicon layer 100. In some embodiments, the silicon layer may be any other suitable semiconductor material, such as germanium and gallium arsenide (GaAs) and the like. The SOI device 50 also includes an insulator layer 102 that is sandwiched between the silicon layer 100 and a substrate 104. The insulator layer 102 may include a suitable insulator, such as an oxide (e.g., silicon dioxide) that is buried under the silicon layer 100 as a “buried oxide.” Additionally or alternatively, the insulator layer 102 may include any other suitable insulators such as sapphire when used for high-performance radio frequency or radiation-sensitive applications. The substrate 104 may be made of any suitable materials such as a silicon wafer on which traditional bulk MOSFET devices may be built.

The SOI device 50 may include a transistor formed on the SOI device 50. In such embodiments, the SOI device 50 includes a gate terminal 106, a terminal 108, and a terminal 110. The terminal 108 and the terminal 110 are respectively shown as the source and the drain of the transistor of the SOI device 50. However, in the SOI device 50 the source may be either of the non-gate terminals: the terminal 108 and the terminal 110. Specifically, the source of the transistor may be whichever of the terminal 108 and the terminal 110 that has the lowest voltage.

The insulation layer 102 is used to at least partially mitigate disturb issues from other circuitry. For instance, FIG. 3 shows an embodiment of circuitry 120 that may use transistors 121 (individually referred to as transistors 121A, 121B, and 121C). These transistors 121 may use respective wordlines (WL) 122 (individually referred to as WLs 122A, 122B, and 122C) to selectively couple signals, such as a global digit line (GDL) 124 to a local digit line (LDL) 126. LDL 126 couples to various memory cells while the GDL 124 may selectively couple to various different LDLs as a branching mechanism. So, to select a specific memory cell/row/column, the memory device 10 may use the GDL 124 to couple to a specific LDL 126 based on assertion of the corresponding WL 122A. However, the other transistors 121B and 121C may couple to other circuitry that has their own respective (parasitic) capacitances 128 (individually referred to as capacitances 128A and 128B). Due to such small distances, the transistor 121A may be very close to the transistor 121B and may be capacitively coupled to the transistor 121B and receive charge from the capacitance 128A.

Returning to FIG. 2, the depth of the silicon layer 100 determines whether the SOI device 50 is a fully depleted SOI (FDSOI) or a partially depleted SOI (PDSOI). The depth of silicon layer 100 of an FDSOI transistor is shallower than the depth of the silicon layer 100 of a PDSOI transistor. Since a bottom side of the SOI device 50 may couple to other circuitry, this coupling may cause a disturb event to the SOI device 50 potentially even in FDSOI devices. To mitigate such disturb issues, the silicon layer 100 may use well doping. For instance, the silicon layer 100 may use a p-type dopants and/or n-type dopants. P-type dopants may include boron, aluminum, gallium, indium, or any other dopant that acts as an acceptor that creates holes in the silicon layer that can accept electrons. N-type dopants may include phosphorus, arsenic, antimony, bismuth, lithium, or any other dopant that acts as a donor that, when added to the silicon layer 100, provides weakly bonded electrons that may be liberated to move through the silicon layer 100 as a charge carrier. By adding doped wells (e.g., boron doped well) in regions 112 and/or 114, the wells may require thicker silicon than may be available in FDSOI leading the SOI device 50 to be a PDSOI. A body 116 is a region between the regions 112 and 114 that is differently doped than the regions 112 and/or 114. For instance, if the regions 112 and 114 are n-type doped (e.g., using boron), the body 116 may be p-type doped (e.g., using phosphorus). In a PDSOI, some portion 118 remains undepleted. As previously noted, electrons may flow toward the drain (e.g., terminal 110), and holes may flow toward the source (e.g., terminal 108). Since there is a potential barrier to holes at the source end, holes may accumulate near the region 112 but still in the body 116. As more holes accumulate, the potential in the body 116 increases. Since PDSOI enables more holes to accumulate in the body 116 than FDSOI, the potential may be higher in the PDSOI. If the potential becomes high enough it results in a bias that causes the threshold voltage for the transistor to drop thereby increasing drain current. These may cause a “kink” in current voltage characteristics of the transistor.

FIG. 4 is a graph 140 showing current voltage characteristics by plotting a voltage 142 that is the voltage difference between drain and source (V_{DS}) against a current 144 that is the current at the drain (ID). The graph 140 includes curves 146, 148, and 150 for different gate to source voltages (Vgs) that all deflect at a kink 152 due to the increased drain current when a sudden increase of saturation current occurs in a strong inversion condition as is one of the major drawbacks of SOI as the body 116 remains floating causing floating body effects (FBE). Furthermore, this FBE can lead to higher currents (Ioff) as leakage current when the device should be off.

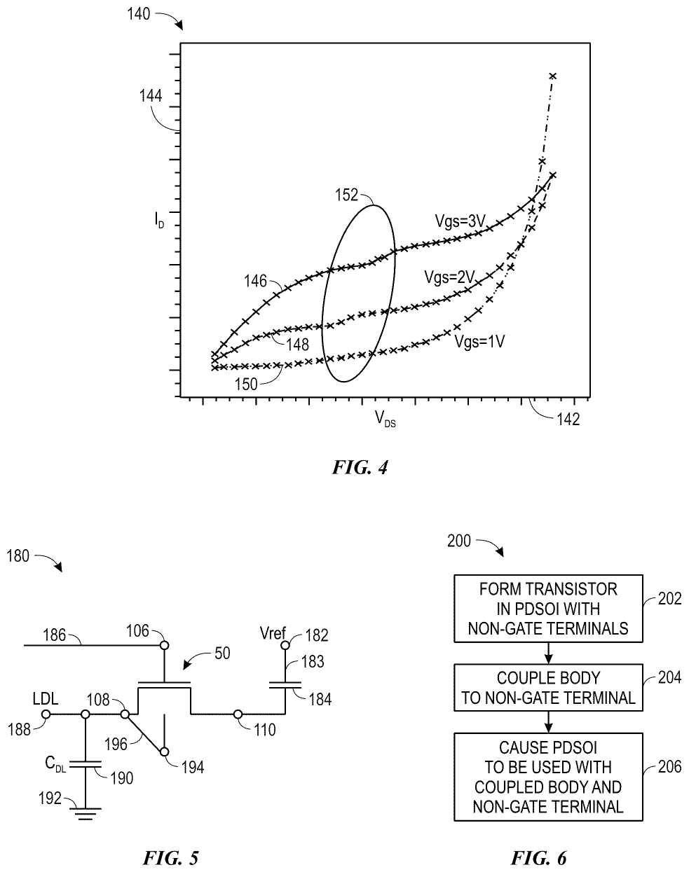

To mitigate FBE issues, the body 116 may be coupled to one of the non-gate terminals, such as the terminals 108 or 110. For instance, in a memory device 10, the body 116 may be coupled to a corresponding LDL since the LDL often is a lower voltage than the GDL meaning that the voltage difference (V_{BS}) between the body 116 and the source of the transistor is often 0V. Furthermore, since the body voltage is deterministic, the risk of sudden increase of saturation current in a kink is eliminated or reduced. Thus, the body potential will not be arbitrarily risen by disturb events to increase Ioff. FIG. 5 is a circuit diagram of circuitry 180 that may utilize the SOI device 50 with FBE mitigation. As illustrated, the circuitry 180 includes a reference voltage 182 that may be carried on global digit line (GDL) 183 that has its own capacitance 184. The GDL 183 couples to the terminal 110 of the transistor of the SOI device 50. As previously noted, the gate terminal 106 couples to a word line (WL) 186 that is used to turn the transistor on and off. The other non-gate terminal 108 is coupled to a local digit line (LDL) 188. The LDL 188 may have its own capacitance 190 between the LDL 188 and ground 192. The illustrated embodiment of the transistor of the SOI device 50 includes a body terminal 194 that is coupled to the terminal 108 and to the LDL 188 via a connector 196 or short. As previously noted, this short between the LDL 188 and the body 116 causes the voltage of the body 116 to be the same as the voltage of the LDL 188 at all times meaning that the voltage of the body 116 is well-defined/deterministic while also reducing or eliminating the likelihood of disturb events causing body potential changes and possibly increasing Ioff.

Since the voltage of the LDL 188 and the GDL 183 may be different voltage levels for different modes of operation, the source may switch between the terminals 108 and 110 in the transistor. In various different modes, this shorting the body 116 to the LDL 188 may have a deterministic voltage difference (V_{BS}) between the body 116 and the source. When the LDL 188 and the GDL 183 have the same voltage, V_{BS} and V_{DS} are both zero. For instance, during an activate (ACT) operation for selected and unselected transistors, an ACT Cell1 for a selected transistor, ACT Cell0 for a selected transistor, for some schemes of idle states, and/or other operations/modes, the LDL 188 and the GDL 183 may be same value with V_{BS} and V_{DS} both being 0 V. In these situations, no current flows through the transistor.

In situations where the terminal 108 to which the LDL 188 is connected is the lower voltage when compared to the terminal 110 to which the GDL 183 is connected, the V_{BS} is 0 V since the body 116 is coupled to the source. For instance, during an ACT Cell1 for selected and unselected transistors, during precharge (PRE) Cell1 for unselected transistors, some idle states, and/or other operations/modes, the voltage of the LDL 188 is less than the voltage of the GDL 183 meaning that V_{BS} is still 0 V. In such situations, there is no leakage current.

In some embodiments and situations where the voltage of the terminal 108 and the LDL 188 is greater than the voltage of the terminal 110 and the GDL 183, some current may leak through the transistor. However, if the operation is a read operation, the voltage difference may be relatively small (e.g., 0.1 V) that merely causes the read operation to be accelerated. In other operations/modes, such as PRE Cell0 for unselected transistors, ACT Cell0 for selected and unselect transistors, and/or other operations/modes, there may be relatively small leakage current through the transistor. This current may result from a voltage difference between the LDL 188 and the GDL 183 where the LDL 188 is higher than the GDL 183. However, this voltage difference may be small even in a worst case (e.g., <0.2 V, <0.3 V, <0.4 V, <0.5 V, etc.). This relatively small voltage difference may cause the transistor to at least partially open to enable a relatively small current to flow through the transistor. For instance, this current may be as little as 100 s of pA to 10 s of nA. Thus, the shorting of the body 116 to the terminal 110 may increase leakage current for some modes in some situations in exchange for the deterministic nature of the voltage of the body 116. However, if this minimal current is within specification for the memory device 10, the tradeoff is worth the exchange. Indeed, even in the unlikely but absolutely worst case where all transistors (e.g., on the order of 1000 s) that act as demultiplexers for respective LDLs 188, the leakage current would account for less than 0.5% of the total power of the memory device. Furthermore, even in this unlikely but absolutely worst case, all of these potential currents would be insufficient to flip logic in the GDL 183.

FIG. 6 is a block diagram of a process 200 for using a PDSOI device. The process 200 includes forming a PDSOI-based transistor or acquiring a transistor with non-gate terminals (block 202). The non-gate terminals (e.g., terminals 108 or 110) are capable of acting as a source or gate terminal for the transistor and may switch between such roles. The process 200 also includes coupling the body 116 to one of the non-gate terminals (block 204). Coupling the body 116 to one of the non-gate terminals may include any of the foregoing discussed configurations, such as the circuitry 180. For instance, the non-gate terminal 110 coupled to the LDL 188 may be shorted to the body 116 (e.g., via a body terminal of the transistor). In some embodiments, the short may be completed when formation of the transistor is performed or may be performed at a later time. With the short in place, the process 200 continues by causing the PDSOI to be used with the coupled body 116 and non-gate terminal (block 206). As previously noted, using the PDSOI with the short between the body 116 and the non-gate terminal 110 results in a deterministic voltage of the body 116.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. An electronic device, comprising:
a partially depleted silicon on insulator (PDSOI) device that comprises a transistor, wherein the transistor comprises:
a gate terminal;
a first non-gate terminal; and
a second non-gate terminal, wherein the first non-gate terminal is coupled to
a body of the PDSOI device.

2. The electronic device of claim 1, wherein the first non-gate terminal and the second non-gate terminal are each configured to act as a source and a drain of the transistor based at least in part on the respective voltages of the first non-gate terminal and the second non-gate terminal.

3. The electronic device of claim 1, wherein the transistor comprises a body terminal through which the coupling of the first non-gate terminal and the body is made.

4. The electronic device of claim 1, wherein the electronic device comprises a memory device that comprises a plurality of local digit lines (LDL).

5. The electronic device of claim 4, wherein the memory device comprises a plurality of transistors formed using PDSOI devices, and the respective LDLs of the plurality of LDLs of the memory device are coupled to respective first non-gate terminals of the plurality of transistors.

6. The electronic device of claim 5, wherein the memory device comprises a global digit line (GDL).

7. The electronic device of claim 6, wherein the GDL is coupled to second non-gate terminals of the plurality of transistors of the memory device.

8. The electronic device of claim 1, wherein electronic device comprises a memory device that comprises:
a local digit line (LDL) coupled to the first non-gate terminal;
a global digit line (GDL) coupled to the second non-gate terminal; and
a word line (WL) coupled to the gate terminal.

9. A method, comprising:
forming a transistor in a partially depleted silicon on insulator (PDSOI) having a first non-gate terminal and a second non-gate terminal;
coupling a body of the PDSOI to the first non-gate terminal; and
causing the PDSOI to be used with the body coupled to the first non-gate terminal.

10. The method of claim 9, wherein causing the PDSOI to be used with the body coupled to the first non-gate terminal comprises alternating the first non-gate terminal and the second non-gate terminal between source and drain roles for the transistor.

11. The method of claim 9, comprising coupling a gate terminal of the transistor to a word line (WL) of a memory device.

12. The method of claim 11, comprising coupling the first non-gate terminal to a local digit line (LDL) of the memory device, wherein the LDL corresponds to the WL of the memory device.

13. The method of claim 12, comprising coupling the second non-gate terminal to a global digit line (GDL) of the memory device.

14. The method of claim 13, wherein causing the PDSOI to be used comprises causing performance of one or more memory operations for a memory cell coupled to the LDL.

15. The method of claim 14, wherein the one or more memory operations comprise the transistor selecting the memory cell by asserting a signal on a WL.

16. A memory device, comprising:
a plurality of memory cells;
a local digit line (LDL) coupled to at least one of the plurality of memory cells; and
a partially depleted silicon on insulator (PDSOI) device that comprises a transistor, wherein the transistor comprises:
a gate terminal;
a first non-gate terminal coupled to the LDL; and
a second non-gate terminal, wherein the first non-gate terminal is coupled to
a body of the PDSOI device.

17. The memory device of claim 16, comprising a global digit line (GDL) coupled to the second non-gate terminal.

18. The memory device of claim 16, comprising a word line (WL) coupled to the gate terminal.

19. The memory device of claim 16, wherein the first non-gate terminal and the second non-gate terminal are each configured to act as a source and a drain of the transistor based at least in part on the respective voltages of the first non-gate terminal and the second non-gate terminal.

20. The memory device of claim 16, comprising:
a plurality of LDLs including the LDL; and
a plurality of demultiplexing transistors formed using PDSOI devices, wherein the plurality of demultiplexing transistors comprises the transistor, and the respective LDLs of the plurality of LDLs of the memory device are coupled to respective first non-gate terminals of the plurality of transistors.
